(19) United States
(12) Patent Application Publication
(10) Pub. No.: US 2012/0114975 A1
(43) Pub. Date: May 10, 2012

(54) Sputtering Targets And Recording Materials Of Hard Disk Formed From The Sputtering Target

(75) Inventors: Wen-Tsang Liu, Tainan (TW); Shou-Hsien Lin, Tainan (TW)

(73) Assignee: Solar Applied Materials Technology Corp., Tainan (TW)

(21) Appl. No.: 13/273,294

(22) Filed: Oct. 14, 2011

(30) Foreign Application Priority Data
Nov. 5, 2010 (TW) 099138114

(51) Int. Cl. G11B 5/62; C23C 14/14; C23C 14/08; C23C 14/34; C23C 14/06

(52) U.S. Cl. 428/826; 204/298.13

(57) ABSTRACT

Disclosed is a sputtering target and its application to the recording material of hard disks wherein the sputtering target comprises cobalt-platinum (CoPt), cobalt-chrome-platinum (CoCrPt) or cobalt-chrome-platinum-boron (CoCrPtB) and a combination of oxides. A recording material is formed by the sputtering target through the sputtering process as a high areal recording density hard disk, which essentially has silica oxide (SiO₂) and Cr₂O₃, wherein the amount of silica oxide (SiO₂) ranges from 4 to 8 atomic % and the amount of chromium oxide (Cr₂O₃) ranges from 0.8 atomic % to 5 atomic %. The present invention is characterized by Cr₂O₃ as an oxygen supplier during sputtering process to donate oxygen to the oxygen defects. The sputtering target containing the combination of oxides is used to form a recording material applied as a recording layer of magnetic recording medium of hard disks, resulting in enhancement of the areal recording density of medium storage.

### BACKGROUND OF THE INVENTION

1. Field of the Invention

The present invention relates to a storing medium, and particularly to a sputtering target and its application to the recording material of hard disks.

2. Description of Related Art

The conventional magnetic recording techniques of a hard disk are classified into two categories according to the orientation of the magnetization: longitudinal magnetic recording and perpendicular magnetic recording. In longitudinal magnetic recording, the magnetic flux is aligned longitudinal to the surface of the disk, whereas in perpendicular magnetic recording, the magnetic flux is aligned perpendicular to the surface of the disk. As shown in FIG. 1, a current perpendicular magnetic recording medium consists of a substrate (glass or Aluminum), an adhesive layer, a soft underlayer, a seed layer, an intermediate layer, a recording layer, a covering layer and a lubricative layer, wherein the most critical technique lies in manufacturing the recording layer.

As shown in FIG. 2, in IEEE Trans. Magn., 38 (2002) 1976 disclosed is that adding oxides into the very thin Co—Pt based magnetic recording layer can effectively make the oxides segregate at the grain boundary without destroying the grain structure of the Co-based magnetic grain, including the Hexagonal Close Packed (HCP) and c-axis orientation, and thereby the grain size is reduced to less than 10 nm and the signal-to-noise ratio is raised.

As mentioned above, a microstructure with granular magnetic thin film with good magnetic properties, high thermal stability and recording performance can be obtained by addition of oxides, which results in the high-density perpendicular recording media being achievable. As shown in FIG. 1, the conventional recording layer of a hard disk consists of multiple layers, the first layer directly above the intermediate layer is called Mag.1, and the subsequent upper layers in sequence are the second layer (Mag.2), the third layer (Mag.3), and so on. The Mag.1 has a structure that ferromagnetic grains are uniformly distributed within the oxides, such that the nonmagnetic oxides can cause well magnetic isolation of the magnetic crystal grains and reduce the noise in the recording media.

Regarding the current materials for use in the recording layers of hard disks, the JP patent publication 2007-031808 discloses that the addition of 0.01 to 0.5% chromium oxide to the sputtering target used in sputtering process enhances the adhesion of silicon dioxide (SiO₂) to cobalt-chrome-platinum (CoCrPt)-based alloy, and also reduces the particles formed during the sputtering process.

The Taiwan patent No. 270060, corresponding to the US patent publication No. 20080062575, discloses use of nonmagnetic silica (Si) as the substrate for disk, and at least one oxide selected from the group consisting of silicon oxide (SiO₂), titanium dioxide (TiO₂), chromium oxide (Cr₂O₃), titanium oxide (TiO) and tantalum oxide (Ta₂O₅) in the grain boundary (G.B.) layer.

US patent publication No. 20020187368 discloses that adding a second oxide in the sputtering target can supply oxygen to the silicon oxide (SiO₂) for the depletion of oxygen thereof during the sputtering process and avoid the formation of mono silica. The disclosure of the above patent mentions that the amount of chromium oxide (Cr₂O₃) used as the second oxide is 1 atomic %.

US patent publication No. 20070042227 discloses that adding different oxides, which have large difference in the standard free energy (ΔG°) of oxide formation of metals, will facilitate the occurrence of redox reaction between oxides and accelerate the dispersion of the atoms. As shown in Table 1, the above patent discloses composites containing oxides including A, B and C type oxides in an amount of 2 mol %, and D or E type oxides in an amount of 0 or 2 mol %.

TABLE 1

| A | B | C | D | E | SNRm(dB) |
|---|---|---|---|---|---|
| Y₂O₃ | SiO₂ | Cr₂O₃ | — | — | 21.8 |
| WO₃ | SiO₂ | Cr₂O₃ | — | — | 21.9 |
| MgO | SiO₂ | Cr₂O₃ | — | — | 21.7 |
| Al₂O₃ | SiO₂ | Cr₂O₃ | — | — | 21.4 |
| ZrO₂ | SiO₂ | Cr₂O₃ | — | — | 21.3 |
| HfO₂ | SiO₂ | Cr₂O₃ | — | — | 21.8 |
| Y₂O₃ | SiO₂ | Cr₂O₃ | Ta₂O₅ | — | 21.7 |
| WO₃ | SiO₂ | Cr₂O₃ | Ta₂O₅ | — | 21.8 |
| MgO | SiO₂ | Cr₂O₃ | Ta₂O₅ | — | 20.5 |
| Al₂O₃ | SiO₂ | Cr₂O₃ | Ta₂O₅ | — | 20.9 |
| ZrO₂ | SiO₂ | Cr₂O₃ | Ta₂O₅ | — | 20.1 |
| HfO₂ | SiO₂ | Cr₂O₃ | Ta₂O₅ | — | 21.1 |
| Y₂O₃ | SiO₂ | Cr₂O₃ | Ta₂O₅ | CeO₂ | 21.6 |
| WO₃ | SiO₂ | Cr₂O₃ | Ta₂O₅ | CeO₂ | 21.5 |
| MgO | SiO₂ | Cr₂O₃ | Ta₂O₅ | CeO₂ | 21.1 |
| Al₂O₃ | SiO₂ | Cr₂O₃ | Ta₂O₅ | CeO₂ | 20.7 |
| ZrO₂ | SiO₂ | Cr₂O₃ | Ta₂O₅ | CeO₂ | 20.2 |
| HfO₂ | SiO₂ | Cr₂O₃ | Ta₂O₅ | CeO₂ | 20.7 |
| 6 mol % SiO₂ | | | | | 17.9 |
| 8 mol % SiO₂ | | | | | 18.5 |
| 10 mol % SiO₂ | | | | | 18.2 |

US patent publication No. 20060121319 discloses that the density of binary oxides is greater than the average density of two metal oxides. Thus, when the recording layer material is being deposited on an intermediate layer, the formation of the porous structure will be reduced. US patent publication No. 20090257144 discloses that properly adjusting the concentration of Cr of CoCrPt based target in combination with using SiO₂ as the first oxide and TiO₂, Ta₂O₅, Nb₂O₅ as the second oxide reduces Co concentration in the grain boundary and thus improves signal-to-noise ratio (SNR).

Although the cited references disclose that the aforementioned materials of the recording layer provide the recording functions, still there are some disadvantages as below:

1. A composite target containing oxides can be bumped out oxygen atom from part of component oxide during the sputtering process. While the oxygen atom is easily evacuated from the sputtering chamber by the vacuum apparatus, the lack of oxygen atoms results in the oxide deposited on the recording medium becoming non-stoichiometric. Accordingly, the non-stoichiometric oxide cannot achieve a well isolation of the magnetic grains.

2. In order to resolve the disadvantage as described above, to gain the stoichiometric oxide during sputtering process, supplement of oxygen into gas during the sputtering process is required. However, it is difficult to precisely control the flow of gas, and is very likely to cause poison on the surface of the sputtering target.

### SUMMARY OF THE INVENTION

In order to solve the aforementioned problems of the conventional recording material of hard disks, the required oxygen is directly added into the sputtering target instead of being added to the gas. The common oxides for supplying the oxygen are Cr₂O₃ and CoO. Therefore, the present invention provides a sputtering target and its application to the recording material of hard disks, wherein the sputtering target essentially consisting of multi-oxides is used to form a recording layer with high quality and high recording density.

The present invention provides a sputtering target essentially consisting of cobalt-platinum (CoPt), cobalt-chrome-platinum (CoCrPt) or cobalt-chrome-platinum-boron (CoCrPtB)-based material and a combination of oxide. The oxide composition includes silica oxide (SiO₂) in an amount of 4 to 8 atomic % and chromium oxide (Cr₂O₃) in an amount of 0.8 to 5 atomic %.

Preferably, the sputtering target containing the combination of oxides includes at least one oxide selected from the group consisting of titanium dioxide (TiO₂), tantalum oxide (Ta₂O₅), niobium oxide (Nb₂O₅), zirconium oxide (ZrO₂), yttrium oxide (Y₂O₃) and hafnium oxide (HfO₂).

Preferably, the sputtering target containing the combination of oxides includes a substance selected from the group consisting of Cu, CuO and a combination thereof.

The present invention provides a recording material of hard disks that is formed from said sputtering target by sputtering.

The recording material for a magnetic recording medium, i.e. hard disk, can be formed by the known sputtering methods including but not limited to ion beam sputtering, electron sputtering deposition, etc.

A preferred embodiment of the present invention is made by the steps of: providing a substrate (such as glass or Aluminum) with deposited layers as in the conventional perpendicular magnetic recording medium and sputtering the sputtering target in accordance with the present invention in an atmospheric pressure of 10 mTorr Argon (Ar) gas onto the top of the layers to form a recording material of hard disks in accordance with the present invention.

The present invention provides a recording material of hard disks essentially consisting of cobalt-platinum (CoPt), cobalt-chrome-platinum (CoCrPt) or cobalt-chrome-platinum-boron (CoCrPtB)-based alloy and a combination of oxides, wherein the combination of oxides includes silica oxide (SiO₂) in an amount of 4 to 8 atomic % and chromium oxide (Cr₂O₃) in an amount of 0.8 to 5 atomic %.

Preferably, the combination of oxides further includes at least one oxide selected from the group consisting of titanium dioxide (TiO₂), tantalum oxide (Ta₂O₅), niobium oxide (Nb₂O₅), zirconium oxide (ZrO₂), yttrium oxide (Y₂O₃) and hafnium oxide (HfO₂).

Preferably, the combination of oxides further includes a substance selected from the group consisting of Cu, CuO and a combination thereof.

Preferably, the amount of the combination of oxides in terms of volume percentage relative to the whole material ranges from 25 to 31 vol. %.

The present invention provides a sputtering target and its application to recording material of hard disks. The improvement comprises:

1. The core ingredient of the sputtering target comprises multiple oxides, wherein CoO or Cr₂O₃ acts as the oxygen supplier to donate oxygen for depletion of oxygen in the sputtering process. Furthermore, the magnetic recording layer formed from said sputtering target can be widely used in the magnetic recording media hard disks to improve the areal recording density of the recording media.

2. If the CoO or Cr₂O₃ in the combinations of oxides exists as a bonding form of Cr—O or Co—O between the magnetic grains and the oxides grain boundary layer, the respective magnetic grains can be surrounded by the oxides more completely and uniformly. Furthermore, the anti-ferromagnetic property of CrO effectively achieves magnetic decoupling within respective magnetic grains, thereby efficiently improving the signal-to-noise ratio (SNR) and the coercivity (Hc) of the thin film.

In the following description of the preferred embodiment, reference is made to the accompanying drawings that form a part thereof, which is shown by way of illustration of specific embodiment in which the invention may be practiced. It is to be understood that other embodiment may be utilized and changes may be made without departing from the scope of the present invention.

### BRIEF DESCRIPTION OF THE DRAWINGS

FIG. 1 is an illustrative scheme of the structure of the conventional perpendicular magnetic recording media;

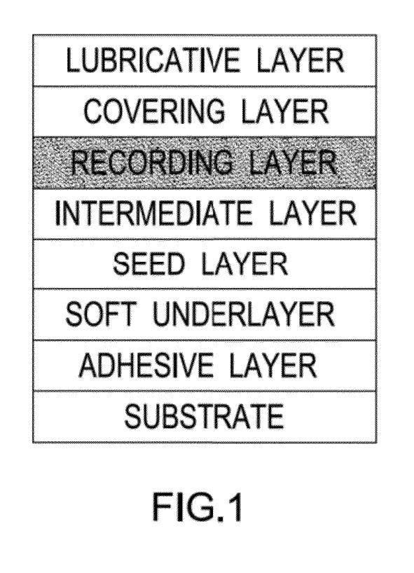

FIG. 2 illustrates a microstructure of the CoCrPt-oxide film shown under Transmission Electron Microscope (TEM) (Reference; IEEE Trans. Magn., 38:1976 (2002)).

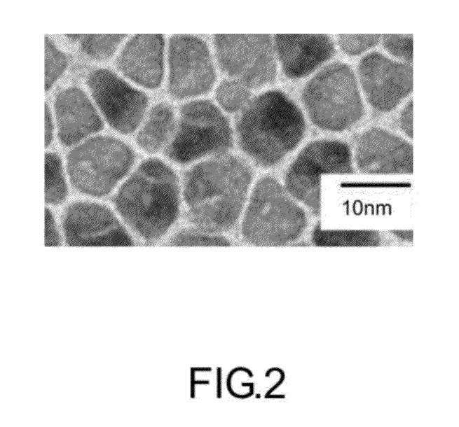

### DETAILED DESCRIPTION OF PREFERRED EMBODIMENT

For a better understanding about the technical features of the present invention and its effect, and for implements in accordance with the disclosures of the specification, preferred embodiment, details and figures are further shown as follows.

The present invention provides a core ingredient of the sputtering target comprising multi-oxides to effectively suppress the interaction of the magnetic grains in the recording layer of hard disks, wherein the multi-oxides comprise:

(1) SiO₂ as the first oxide,

(2) Substance selected from TiO₂, Ta₂O₅, Nb₂O₅, ZrO₂, Y₂O₃, HfO₂ and CuO as the second oxide, and

(3) Cr₂O₃ or CoO as the third oxide.

The main technical feature of the present invention resides in the third oxide, which has characteristics as below:

(1) Being an oxygen supplier, which is capable of making the first oxide and the second oxide stoichiometric in the sputtering process without need of adding extra oxygen to the gas in the sputtering process,

(2) Existing in a bonding form of Cr—O or Co—O between the magnetic grains and the oxide grain boundary layer, which improves wettability and makes magnetic grains surrounded more completely and uniformly by the oxide grain boundary layer.

(3) Since there exists a bonding form of Cr—O or Co—O between the magnetic grains and the oxide grain boundary layer, it is effective in achieving magnetic decoupling between the magnetic grains and the oxide grain boundary layer due to the anti-ferromagnetic property of Cr—O.

For the first oxide, SiO₂ is used as glass former, which can form a compact grain boundary layer with a smooth surface. For the second oxide, the oxide having high melting temperature is used, which can nucleate first during the formation of thin film to refine the magnetic grains during the sputtering process. For the third oxide, the oxide with the Gibbs free energy that is higher than that of the first and the second oxides is used, wherein the metal element in said third oxide is easier to be oxidized than Co and Pt.

The present invention provides a sputtering target essentially consisting of cobalt-platinum (CoPt), cobalt-chrome-platinum (CoCrPt) or cobalt-chrome-platinum-boron (CoCrPtB)-based alloy and a combination of oxides. The combination of oxides includes silica oxide (SiO₂) and chromium oxide (Cr₂O₃), wherein the amount of silica oxide ranges from 4 to 8 atomic % and the amount of chromium oxide ranges from 0.8% to 5%.

The combination of oxides in the sputtering target further includes at least one oxide selected from the group consisting of titanium dioxide (TiO₂), tantalum oxide (Ta₂O₅), niobium oxide (Nb₂O₅), zirconium oxide (ZrO₂), yttrium oxide (Y₂O₃), and hafnium oxide (HfO₂).

The combination of oxides in the sputtering target further includes a substance selected from Cu, CuO and a combination thereof.

The present invention provides a recording material for hard disks with high quality and high areal recording density, which is formed by sputtering the sputtering target. The recording material for a magnetic recording medium/hard disks is formed by any of the conventional sputtering methods, including but not limited to ion beam sputtering, electron sputtering deposition, etc. A preferred embodiment of the present invention is obtained by the following steps:

providing a substrate (such as glass or Aluminum) with deposited layers as in the conventional perpendicular magnetic recording medium and sputtering the sputtering target in accordance with the present invention in an atmospheric pressure of 10 mTorr Argon (Ar) gas onto the top of the layers to form a recording material of hard disks in accordance with the present invention.

The present invention also provides an application of said sputtering target to recording material of hard disks with high quality and high areal recording density, wherein the sputtering target comprises cobalt-platinum (CoPt), cobalt-chrome-platinum (CoCrPt) or cobalt-chrome-platinum-boron (CoCrPtB)-based alloy and a combination of oxides. The combination of oxides includes silica oxide (SiO₂) and chromium oxide (Cr₂O₃), wherein the amount of silica oxide ranges from 4 to 8 atomic % and the amount of chromium oxide ranges from 0.8% to 5%.

The combination of oxides of the recording material of hard disks further includes at least one oxide selected from the group consisting of titanium dioxide (TiO₂), tantalum oxide (Ta₂O₅), niobium oxide (Nb₂O₅), zirconium oxide (ZrO₂), yttrium oxide (Y₂O₃) and hafnium oxide (HfO₂).

The combination of oxides of the recording material of hard disks further includes a substance selected from the group consisting of Cu, CuO and a combination thereof.

The amount of the combination of oxides of the recording material of hard disks in terms of volume percentage relative to the whole material ranges from 25 to 31 vol. %.

### Example

A sputtering target A composed of CoCrPt-x(SiO₂)-y(2nd oxide)-z(Cr₂O₃) and a sputtering target B composed of CoCrPt-x(SiO₂)-y(2nd oxide)-z(ZrO₂) were respectively prepared, wherein the x, y and z represented atom % of corresponding oxide, wherein “z” ranged from 0.8 to 5 atomic % (0.8%≦z≦5%), and “x+y” ranged from 6 to 11 atomic % (6%≦x+y≦11%). A substrate with the multiple layers was prepared by laminating layers in order on a substrate as in conventional method for manufacturing perpendicular magnetic recording medium. A recording layer was formed by sputtering with the sputtering target in accordance with the present invention at an Argon (Ar) gas pressure of 10 mTorr, followed by sputtering a CoCrPtB layer thereon. The coercivity (Hc) and the nucleation field (Hn) thereof were then measured by vibrating sample magnetometer (VSM), and the signal-to-noise ratio (SNR) thereof was measured by Guzik test system.

With reference to Table 2, comparing the sputtering targets A and B, the sputtering target containing Cr₂O₃ had a better SNR and Hc than that without Cr₂O₃. Especially for the sputtering target containing Cr₂O₃ in an amount more than 2 atomic %, its SNR and Hc were obviously improved. To sum up, the results of the experiment showed that inclusion of Cr₂O₃ in the target for use in hard disk would effectively enhance SNR and Hc. Furthermore, in a preferred embodiment of hard disk, the CoCrPt layer thereof further included boron (B).

TABLE 2

| | | | | | | | Signal- | | Oxide |
|---|---|---|---|---|---|---|---|---|---|
| Component (atomic percentage, at. %) | | | | | | | to-noise | | composition |
| | | | Silica | Titanium | Chromium | zirconium | ratio | | (volume |
| Cobalt | Chromium | Platinum | oxide | oxide | oxide | oxide | (SNR | Coercivity | percentage, |
| (Co) | (Cr) | (Pt) | (SiO₂) | (TiO₂) | (Cr₂O₃) | (ZrO₂) | (dB)) | (Hc (Oe)) | vol. %) |
| estimated value | 7.12 | 17.80 | 6.00 | 4.00 | 1.00 | 0 | 19.30 | 5417 | 29.2 |
| | 7.23 | 18.09 | 5.22 | 3.48 | 0.87 | 0 | 19.52 | 5503 | 26.1 |
| | 7.20 | 18.00 | 6.00 | 1.00 | 3.00 | 0 | 19.69 | 5438 | 29.0 |
| | 7.30 | 18.26 | 5.22 | 0.87 | 2.61 | 0 | 19.59 | 5458 | 25.9 |
| | 7.28 | 18.20 | 4.50 | 3.00 | 0 | 1.50 | 18.65 | 5289 | 24.0 |
| | 7.28 | 18.20 | 4.50 | 1.50 | 0 | 3.00 | 18.58 | 5236 | 24.4 |

The present invention clearly and concisely characterized types and amounts of the oxides applied to the magnetic recording materials, wherein the amount of Cr₂O₃ is more than 0.8 atomic %. The present invention has the following technical features: using a third oxide in addition to a first oxide and a second oxide to supply oxygen during the sputtering process, to enhance adhesion of oxides to magnetic grains and to achieve well isolation of magnetic grains to reduce the coupling effect between the magnetic grains by anti-ferromagnetic property of Cr—O. By use of the sputtering target in accordance with the present invention to form a magnetic recording material applied to the recording layer of the magnetic recording medium/hard disks, the areal recording density of magnetic recording medium can be greatly increased.

Even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

1. A sputtering target essentially consisting of cobalt-platinum (CoPt), cobalt-chrome-platinum (CoCrPt) or cobalt-chrome-platinum-boron (CoCrPtB)-based alloy and a combination of oxides, the combination of oxides including silica oxide (SiO₂) and chromium oxide (Cr₂O₃), wherein the amount of silica oxide (SiO₂) ranges from 4 to 8 atomic % and the amount of chromium oxide (Cr₂O₃) ranges from 0.8 to 5 atomic % or less.

2. The sputtering target according to claim 1, wherein the combination of oxides further comprises at least one oxide selected from the group consisting of titanium dioxide (TiO₂), tantalum oxide (Ta₂O₅), niobium oxide (Nb₂O₅), zirconium oxide (ZrO₂), yttrium oxide (Y₂O₃) and hafnium oxide (HfO₂).

3. The sputtering target according to claim 1, wherein the combination of oxides further comprises a substance selected from Cu, CuO and a combination thereof.

4. (canceled)

5. (canceled)

6. (canceled)

7. A recording material of hard disks, which is formed by the sputtering of a sputtering target which consists essentially of cobalt-platinum (CoPt), cobalt-chrome-platinum (CoCrPt) or cobalt-chrome-platinum-boron (CoCrPtB)-based alloy and a combination of oxides, said combination of oxides including silica oxide (SiO₂) and chromium oxide (Cr₂O₃), wherein the amount of silica oxide (SiO₂) ranges from 4 to 8 atomic % and the amount of chromium oxide (Cr₂O₃) ranges from 0.8 atomic % to 5 atomic % on a substrate.

8. The recording material of hard disks according to claim 7, wherein the combination of oxides further comprises at least one oxide selected from the group consisting of titanium dioxide (TiO₂), tantalum oxide (Ta₂O₅), niobium oxide (Nb₂O₅), zirconium oxide (ZrO₂), yttrium oxide (Y₂O₃) and hafnium oxide (HfO₂).

9. The recording material of hard disks according to claim 8, wherein the combination of oxides further comprises a substance selected from Cu, CuO and a combination thereof.

10. The recording material of hard disks according to claim 9, wherein the amount of the combination of oxides relative to the whole material ranges from 25 to 31 vol. %.
